(19) United States
(12) Patent Application Publication
(10) Pub. No.: US 2026/0282460 A1
(43) Pub. Date: Sep. 17, 2026

(54) SEMICONDUCTOR DEVICE AND METHOD OF FORMING THE SAME

(71) Applicant: Vanguard International Semiconductor Corporation, Hsinchu (TW)

(72) Inventors: Chih-Hung LIN, Taichung City (TW); Chia-Hao LEE, Zhubei City (TW)

(73) Assignee: Vanguard International Semiconductor Corporation, Hsinchu (TW)

(21) Appl. No.: 19/078,765

(22) Filed: Mar. 13, 2025

(51) Int. Cl. H10D 62/10; H10D 30/01; H10D 30/65; H10D 62/13; H10D 64/62

(52) U.S. Cl. CPC H10D 62/102; H10D 30/0281; H10D 30/65; H10D 62/115; H10D 62/157; H10D 64/62

(57) ABSTRACT

A semiconductor device includes a substrate, a first well region, a second well region, a gate structure, a source structure, a drain structure, and an ohmic contact layer. The first well region and the second well region are disposed adjacent to one another in the substrate and have opposite doping types. The gate structure spans the first well region and the second well region. The source structure is disposed in the first well region. The drain structure is disposed in the second well region. The ohmic contact layer is disposed on the second well region to form an ohmic contact with the second well region. The ohmic contact layer is disposed between the gate structure and the drain structure.

### BACKGROUND

### Field of the Invention

The disclosure relates to semiconductor technology, and, in particular, it relates to semiconductor devices with ohmic contact layers and a method of forming the same.

### Description of the Related Art

A laterally-diffused metal-oxide semiconductor (LDMOS) device is a type of MOS power transistor that includes a drift region between the gate and the drain regions. The drift region is a lightly-doped region compared with the dopant concentration of the source and drain regions, which is used to avoid or suppress high electric fields between the source and drain regions. Since LDMOS devices are suitable for use in transmitting high-frequency and high-power electrical signals, they are widely used in high voltage power applications.

On-state resistance (Ron) is an important factor for an LDMOS device that is directly proportional to the power consumption of the LDMOS device. As there are increasing demands for power saving and better performance of electronic devices, manufacturers have continuously sought to reduce the current leakage and Ron of LDMOS devices. Although it has been observed that the Ron of conventional LDMOS devices decreases when the dopant concentration of the drift region increases, the decreased Ron is usually achieved at the expense of reduced off-state breakdown voltage (V_{BD}) in the LDMOS devices. Although existing LDMOS devices are generally adequate for their intended purposes, they have not been entirely satisfactory in every respect.

### SUMMARY

In view of this, it is necessary to provide an improved semiconductor device to reduce on-state resistance without deficiencies related to the breakdown voltage and a method for forming the same.

One aspect of the present pertains to a semiconductor device. The semiconductor device includes a substrate, a first well region, a second well region, a gate structure, a source structure, a drain structure, and an ohmic contact layer. The first well region and the second well region are disposed adjacent to one another in the substrate and have opposite doping types. The gate structure spans the first well region and the second well region. The source structure is disposed in the first well region. The drain structure is disposed in the second well region. The ohmic contact layer is disposed on the second well region to form an ohmic contact with the second well region. The ohmic contact layer is disposed between the gate structure and the drain structure.

Another aspect of the present pertains to a method for forming a semiconductor device. The method includes providing a substrate having a first well region and a second well region. The first well region is disposed adjacent to the second well region, and they have opposite doping types. The method includes forming a gate structure spanning the first well region and the second well region. The method includes forming a source structure in the first well region. The method includes forming a drain structure in the second well region. The method includes forming an ohmic contact layer on the second well region to form ohmic contact with the second well region. The ohmic contact layer is disposed between the gate structure and the drain structure.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIG. 1 is a cross-sectional view of a semiconductor device, in accordance with some embodiments.

FIG. 2 is a current-voltage (I-V) curve obtained by electrical simulation using technology computer-aided design (TCAD).

FIGS. 3-10 are flow diagrams of a method for forming a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As disclosed herein, the term “about” or “substantial” typically mean±20% of the stated value, more typically ±10% of the stated value, more typically ±5% of the stated value, more typically ±3% of the stated value, more typically ±2% of the stated value, more typically ±1% of the stated value, and even more typically ±0.5% of the stated value. The stated value of the present disclosure is an approximate value. That is, when there is no specific description of the terms “about” or “substantial”, the stated value includes the meaning of “about” or “substantial”.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

For illustration purpose, the present disclosure is described as a laterally diffused metal oxide semiconductor (LDMOS) device. However, the present disclosure is not limited thereto. Embodiments of the present disclosure are also applicable to other types of metal oxide semiconductor devices, such as a vertically diffused metal oxide semiconductor (VDMOS) device, an extended-drain metal oxide semiconductor (EDMOS) device or the like. In addition, the present disclosure is also applicable to other types of semiconductor devices, such as a diode, an insulated gate bipolar transistor (IGBT), a bipolar junction transistor (BJT) or the like.

Addressing the drawbacks of the prior art, the present disclosure provides a semiconductor device and a method for forming the same. The semiconductor device includes an ohmic contact layer between a gate structure and a drain structure. The ohmic contact layer is located on the second well region (e.g., the drift region) to form ohmic contact with the second well region, ensuring that the current in the second well region is concentrated near the surface. This reduces the on-resistance (Ron) while maintaining or increasing the off-state breakdown voltage (V_{BD}), thereby improving the reliability of the semiconductor device.

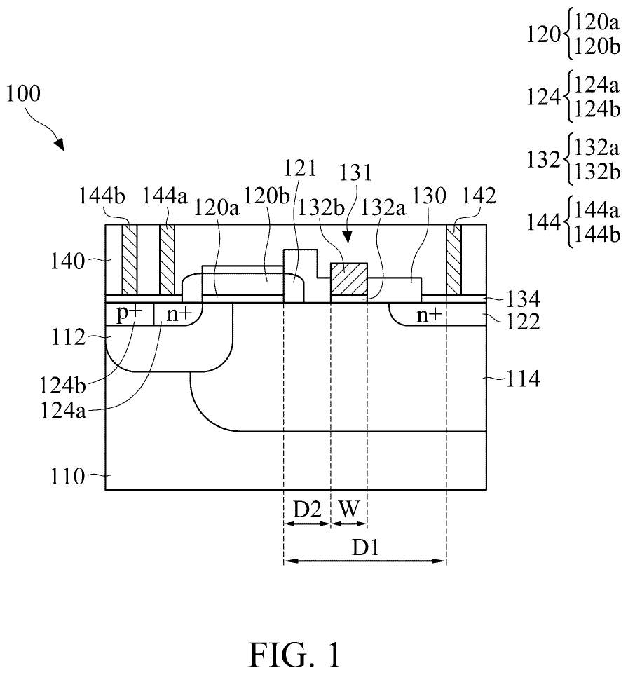

FIG. 1 is a cross-sectional view of a semiconductor device 100, in accordance with some embodiments. Referring to FIG. 1, the semiconductor device 100 includes a substrate 110. The substrate 110 may be a semiconductor substrate and the material of which includes an elementary semiconductor, such as silicon (Si) and/or germanium (Ge); a compound semiconductor, such as gallium nitride (GaN), silicon carbide (SiC), gallium arsenide (GaAs), gallium phosphide (GaP), indium phosphide (InP), indium arsenide (InAs) and/or indium antimonide (InSb); an alloy semiconductor such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP) and/or gallium indium arsenide phosphide (GaInAsP), or a combination thereof. In addition, the substrate 110 may also be a silicon-on-insulator (SOI) substrate. In some embodiments, the substrate 110 may have a first conductivity type, such as a P-type substrate.

In addition, the semiconductor device 100 includes a first well region 112 and a second well region 114. These well regions are adjacent and disposed within the substrate 110, near the top surface of the substrate 110. The first well region 112 and the second well region 114 have opposite doping types. For example, if the substrate 110 has a first conductivity type (e.g., P type), the first well region 112 also has the first conductivity type (e.g., P type), while the second well region 114 has the second conductivity type (e.g., N type). The first well region 112 may be referred to as a body region, and the second well region 114 may be referred to as a drift region. In some embodiments, the first well region 112 (body region) is adjacent to and in direct contact with the second well region 114.

In some other embodiments, the first conductivity type is N-type, and the second conductivity type is P-type. The P-type dopants may include boron (B), gallium (Ga), aluminum (Al), indium (In), boron trifluoride (BF₃) ions, or a combination thereof. The N-type dopants may include phosphorus (P), arsenic (As), nitrogen (N), antimony (Sb) ions, or a combination thereof. Since the dopant concentration of the first well region (body region) 112 is at least 100 times greater than the dopant concentration of the second well region (drift region) 114, the depletion region at the junction of the first well region 112 and the second well region 114 extends mostly in the second well region (drift region) 114 and does not spread into a channel region formed in the first well region (body region) 112. In some embodiments, the dopant concentration of the first well region 112 is about 1E16 atoms/cm³ to about 1E18 atoms/cm³, and the dopant concentration of the second well region 114 is about 1E15 atoms/cm³ to about 1E17 atoms/cm³.

Still referring to FIG. 1, the semiconductor device 100 includes a gate structure 120. The gate structure 120 spans the first well region 112 and the second well region 114. In some embodiments, the gate structure 120 may include a gate dielectric layer 120a located on the first well region 112 and the second well region 114, and a gate electrode 120b located on the gate dielectric layer 120a.

In some embodiments, the gate dielectric layer 120a may include one or more single-layer or multi-layer dielectric materials, such as silicon oxide, silicon nitride, silicon oxynitride, or a combination thereof. In other embodiments, the gate dielectric layer 120a may include metal oxide, metal nitride, metal silicide, metal aluminate, zirconium silicate, zirconium aluminate, or a combination thereof, but the present disclosure is not limited thereto. The material of the gate electrode 120b may include a conductive material, such as a doped semiconductor, a metal or a metal nitride. For example, the doped semiconductor may be doped polycrystalline silicon or doped polycrystalline germanium; the metal may be gold (Au), nickel (Ni), platinum (Pt), palladium (Pd), iridium (Ir), titanium (Ti), chromium (Cr), tungsten (W), aluminum (Al), copper (Cu), similar materials, a combination thereof, or a multilayer structure thereof; the metal nitride may be molybdenum nitride (MoN), tungsten nitride (WN), titanium nitride (TiN), tantalum nitride (TaN), or the like.

In some embodiments, the gate structure 120 further includes a sidewall spacer 121. As shown in FIG. 1, the sidewall spacer 121 is disposed on the opposite sidewalls of the gate dielectric layer 120a and the gate electrode 120b. The sidewall spacer 121 includes one or more layers of insulating material, such as silicon oxide (SiO₂), silicon nitride (SiN), silicon oxynitride (SiON), silicon oxycarbon nitride (SiOCN), or silicon carbon nitride (SiCN).

Still referring to FIG. 1, the semiconductor device 100 includes a source structure 124 located in the first well region 112 and a drain structure 122 located in the second well region 114. The drain structure 122 has a dopant of the same doping type as the second well region 114, and the dopant concentration of the drain structure 122 is greater than the dopant concentration of the second well region 114. In some embodiments, the dopant concentration of the drain structure 122 is about 1E20 atoms/cm³ to about 1E22 atoms/cm³. The source structure 124 may include a first doping region 124a and a second doping region 124b adjacent to each other and having opposite doping types. For example, the first doping region 124a may be N-type, and the second doping region 124b may be P-type. In some other embodiments, the first doping region 124a may be P-type, and the second doping region 124b may be N-type. The dopant concentration of the first doping region 124a and the second doping region 124b is about 1E20 atoms/cm³ to about 1E22 atoms/cm³.

In addition, the semiconductor device 100 further includes an ohmic contact layer 132. As shown in FIG. 1, the ohmic contact layer 132 is disposed on the second well region 114 and between the gate structure 120 and the drain structure 122. Ohmic contact is formed between the ohmic contact layer 132 and the second well region 114, concentrating the current near the surface of the second well region 114 and thereby reducing the on-resistance (Ron). Furthermore, since the surface electric field can be more uniformly distributed, a better charge balance can be achieved. As a result, the off-state breakdown voltage (V_{BD}) can be maintained or increased, thereby improving the reliability of the semiconductor device 100. It should be noted that, in this embodiment, the ohmic contact layer 132 does not contact with either the gate structure 120 or the drain structure 122. If the ohmic contact layer 132 comes into contact with the gate structure 120, it may result in a short circuit, leading to a reduction in the breakdown voltage. On the other hand, if the ohmic contact layer 132 comes into contact with the drain structure 122, a Schottky contact may be formed, which can also reduce the breakdown voltage. In some embodiments, the width W of the ohmic contact layer 132 may range from about 2 μm to about 80 μm. However, the present disclosure is not limited thereto, as long as the ohmic contact layer 132 does not come into contact with either the gate structure 120 or the drain structure 122.

As shown in FIG. 1, the ohmic contact layer 132 may include a silicide layer 132a in direct contact with the second well region 114 and a metal layer 132b stacked on the silicide layer 132a. The silicide layer 132a is made of a metal material capable of forming ohmic contact with a semiconductor material. Accordingly, the silicide layer 132a can form ohmic contact with the second well region 114. In some embodiments, the metal layer 132b may be a floating metal layer. In other words, the ohmic contact layer 132 is electrically isolated from any potential or circuit node to prevent influencing the voltage difference between the gate structure 120 and the drain structure 122.

In some embodiments, the silicide layer 132a may include a metal silicide, such as tungsten silicide, titanium silicide, cobalt silicide, nickel silicide, platinum silicide, erbium silicide, and the like, or a combination thereof. The metal layer 132b may include a metal material such as gold (Au), nickel (Ni), platinum (Pt), palladium (Pd), iridium (Ir), titanium (Ti), chromium (Cr), tungsten (W), aluminum (Al), copper (Cu), similar materials, a combination thereof, or multilayer structures thereof. In some embodiments, the ohmic contact layer 132 has a thickness ranging from about 1 nm to 20 nm, within which the on-resistance can be effectively reduced, and the current density can be increased.

Still referring FIG. 1, the semiconductor device 100 may further include an interlayer dielectric (ILD) layer 140. The ILD 140 is disposed on the substrate 110 and covers the gate structure 120, the source structure 124, the drain structure 122, and the ohmic contact layer 132. The ILD layer 140 may include one or more layers of dielectric materials, such as (SiO₂), silicon nitride (SiN), silicon oxynitride (SiON), tetraethoxysilane (TEOS), phosphosilicate glass (PSG), borophosphosilicate glass (BPSG), low-k dielectric material, and/or other suitable dielectric materials. The low-k dielectric materials may include, but are not limited to, fluorinated silica glass (FSG), hydrogen silsesquioxane (HSQ), carbon doped silicon oxide, amorphous fluorinated carbon, parylene, bis-benzocyclobutenes (BCB), polyimide or other suitable dielectric materials.

In addition, the semiconductor device 100 may include a drain contact 142 and a source contact 144 (including a first source contact 144a and a second source contact 144b) that penetrate through the ILD layer 140 and are electrically connected to the drain structure 122 and the source structure 124, respectively. In some embodiments, the first source contact 144a and the second source contact 144b are electrically connected to the first doped region 124a and the second doped region 124b, respectively. Each of the source electrode 142 and the drain electrode 144 may include a barrier layer (not shown) and a conductive material surrounded by the barrier layer. The barrier layer is used to prevent the conductive material from diffusing into the ILD layer 140. The material of the barrier layer may include titanium nitride (TiN), titanium (Ti), tantalum (Ta), tantalum nitride (TaN), tungsten (W), nitride (WN), other suitable materials, or a combination thereof. The conductive material includes metals (e.g., copper (Cu), aluminum (Al), molybdenum (Mo), tungsten (W), gold (Au), chromium (Cr), nickel (Ni), platinum (Pt), titanium (Ti), iridium (Ir), rhodium (Rh)), alloys thereof, polysilicon, other suitable conductive materials, or a combination thereof.

In some embodiments, as shown in FIG. 1, the gate structure 120 is separated from the drain contact 142 by a first shortest distance D1, and the gate structure 120 is separated from the ohmic contact layer 132 by a second shortest distance D2. The ratio of the second shortest distance D2 to the first shortest distance D1 is greater than about 0.3. If the ratio is less than about 0.3, the gate structure 120 may be short-circuited, thereby causing the breakdown voltage to reduce. Conversely, if the ratio is greater than about 0.3, the ohmic contact layer 132 may cover and contact the drain structure 122, forming a Schottky contact, which can also reduce the breakdown voltage. In some embodiments, the first shortest distance D1 is less than about 3 μm, which helps reduce the size of the semiconductor device 100. The first shortest distance D1 is greater than the width W of the ohmic contact layer 132, so as to prevent the ohmic contact layer 132 from contacting the gate structure 120 and/or the drain structure 122.

In some embodiments, the semiconductor device 100 may include a self-aligned metal silicide 134 disposed on the surfaces of the gate structure 120, the source structure 124, and the drain structure 122, respectively. The self-aligned metal silicide 134 may be formed in a self-aligned manner on the surfaces of the gate structure 120, the source structure 124, and the drain structure 122 to improve electrical conductivity and reduce contact resistance. According to some embodiments of the present disclosure, the self-aligned metal silicide 134 is made of a metal material capable of forming ohmic contact with a semiconductor material. Accordingly, the self-aligned metal silicide 134 can form ohmic contact with the gate structure 120, the source structure 124, and the drain structure 122.

In some embodiments, the semiconductor device 100 may optionally include a resist protective oxide (RPO) layer 130. The RPO layer 130 extends between the gate structure 120 and the drain structure 122, with the ohmic contact layer 132 disposed on the second well region 114, penetrating through the RPO layer 130. As shown in FIG. 1, the RPO layer 130 further extends to cover a portion of the sidewall spacer 121, but the present disclosure is not limited thereto. In other embodiments, the RPO layer 130 does not cover the sidewall spacer 121. The RPO layer 130 may act as a silicide barrier layer to protect the underlying regions (e.g., the second well region 114 and the drain structure 122) from forming silicide during the formation of the self-aligned metal silicide 134. In some embodiments, the material of the RPO layer 130 may include silicon oxide, silicon nitride, silicon oxynitride, or other suitable dielectric materials.

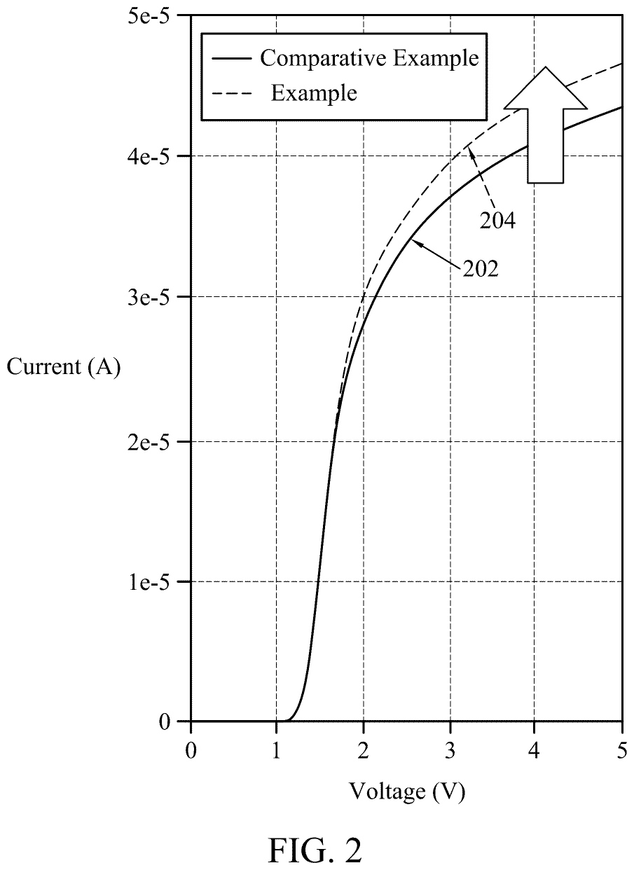

Several examples and comparative examples are provided below. Electrical simulations were performed on semiconductor devices from Comparative Example (absence of an ohmic contact layer) and Example (presence of an ohmic contact layer 132) using the Sentaurus software package from Synopsys' technology computer-aided design (TCAD) tools. Example is an example of the semiconductor device 100 shown in FIG. 1. The design features and the electrical parameters obtained by simulation are shown in Table 1, and the current-voltage (I-V) curve obtained by electrical simulation is shown in FIG. 2. In FIG. 2, a curve 202 represents a current-voltage curve of Comparative Example, and a curve 204 represents a current-voltage curve of Example.

TABLE 1

| | Comparative | |
|---|---|---|
| | Example | Example |
| Distance A (μm) | 1.6 | 1.6 |
| Distance B (μm) | — | 0.5 |
| Distance C (μm) | — | 0.5 |
| Threshold voltage (V) | 1.27 | 1.27 |
| On-state resistance | 11.69 | 10.51 |
| (m O h m * mm²) | | |
| Off-state breakdown voltage (V) | 21.8 | 22.4 |

In Table 1, distance A was defined as the shortest distance (e.g., the first shortest distance D1) between the gate structure (e.g., gate structure 120) and the drain contact (e.g., drain contact 142), distance B was defined as the shortest distance (e.g., the second shortest distance D2) between the gate structure (e.g., gate structure 120) and the ohmic contact layer (e.g., ohmic contact layer 132), and width C was defined as the width of the ohmic contact layer (e.g., ohmic contact layer 132). It should be noted that, to ensure an effective comparison, some parameters (e.g., the distance A) were remain consistent between Comparative Example and Example.

According to Table 1 and the current-voltage curve as shown in FIG. 2, it can be confirmed that, compared to Comparative Example (absence of an ohmic contact layer), the on-state resistance of Example is reduced by approximately 10% while maintaining the threshold voltage, and the off-state breakdown voltage is increased by about 3%. Furthermore, the electrical simulation results show that by disposing the ohmic contact layer 132 between the gate structure 120 and the drain structure 122, the current in the second well region 114 is concentrated near its surface, thereby reducing the on-state resistance (Ron). Moreover, since the surface electric field can be more uniformly distributed, a better charge balance can be achieved, thereby increasing the off-state breakdown voltage (V_{BD}). Therefore, according to the embodiment of the present disclosure, the on-state resistance of the semiconductor device can be reduced by the presence of the ohmic contact layer 132, and the off-state breakdown voltage of the semiconductor device 100 can be increased, thereby improving the reliability of the semiconductor device 100.

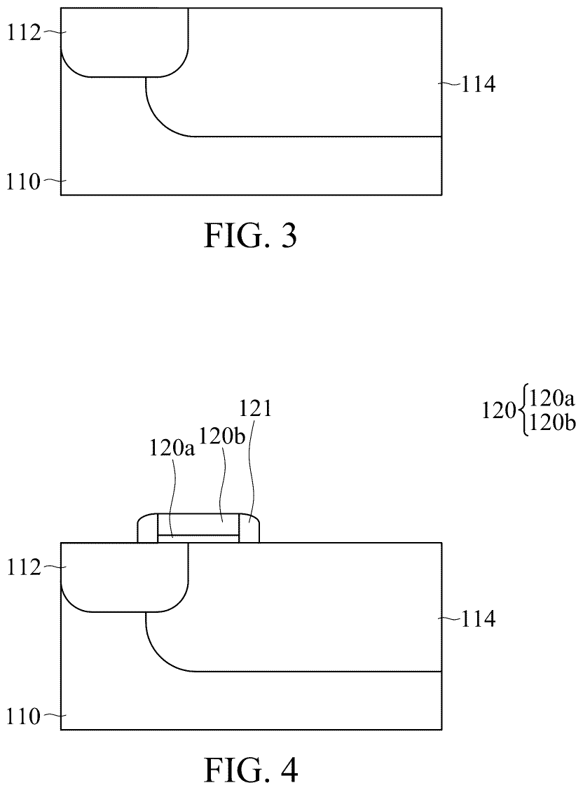

FIGS. 3-10 are flow diagrams of a method for forming a semiconductor device 100, in accordance with some embodiments.

Referring to FIG. 3, a substrate 110 is provided. A first well region 112 and a second well region 114 which are adjacent to each other and have opposite doping types are disposed in the substrate 110. The method for forming the first well region 112 includes, but is not limited to, forming a patterned mask layer (not shown) on the substrate 110 using a lithography process and an etching process. The patterned mask layer exposes the predetermined region of the substrate 110 where the first well region 112 will be formed, while covering the other regions of the substrate 110. Next, dopants are implanted into this predetermined region to form the first well region 112, after which the patterned mask layer is removed. The patterned mask layer may be a hard mask or a photoresist. Next, a second well region 114 may be formed using a similar method.

Next, referring to FIG. 4, a gate structure 120, including a gate dielectric layer 120a and a gate electrode 120b, is formed to span both the first well region 112 and the second well region 114. In some implementations, the dielectric material (not shown) may be formed using spin coating, chemical vapor deposition (CVD), atomic layer deposition (ALD), high-density plasma chemical vapor deposition (HDPCVD), other suitable methods, or a combination thereof. Then, a conductive material (not shown) may be formed by a deposition process such as CVD, ALD, or physical vapor deposition (PVD) process (e.g., sputtering or evaporation). Subsequently, the dielectric material and the conductive material are patterned to form the gate dielectric layer 120a and the gate electrode 120b. The exemplary method for patterning the dielectric material and the conductive material may include forming a photoresist layer on the conductive material using a suitable process (e.g., spin coating), followed by patterning the photoresist layer with a suitable lithography process to form a patterned photoresist mask. Then, the pattern of the photoresist mask may be transferred to the dielectric material and the conductive material underneath by a dry etching process to form the gate dielectric layer 120a and the gate electrode 120b. The photoresist may be stripped later. In some embodiments, a sidewall spacer 121 may be formed on the opposite sidewalls of both the gate dielectric layer 120a and the gate electrode 120b by a deposition and an etching (anisotropic etching) process.

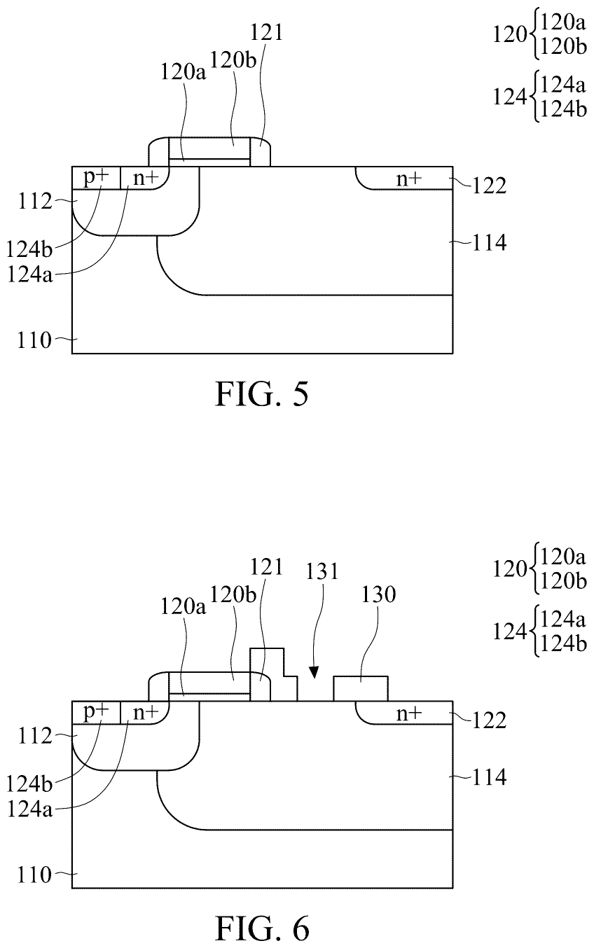

Next, referring to FIG. 5, a source structure 124 and a drain structure 122 are formed in the first well region 112 and the second well region 114, respectively. The formation methods for the doping regions of the drain structure 122 and the source structure 124 are similar to that of the first well region 112 described in FIG. 3, and their descriptions will not be repeated herein for brevity.

Next, referring to FIG. 6, a resist protective oxide (RPO) layer 130 is formed, extending between the gate structure 120 and the drain structure 122. Then, a portion of the RPO layer 130 is recessed to form an opening 131 in the region where an ohmic contact layer 132 is to be formed. This opening 131 exposes a portion of the surface of the second well region 114. It should be noted that the location of the opening 131 determines the location of the ohmic contact layer 132 that is subsequently formed. Therefore, the opening 131 should be located between the gate structure 120 and the drain structure 122. In some embodiments, the etching process for removing the RPO layer 130 may include dry etching, wet etching (e.g., oxide wet etching), or a combination thereof.

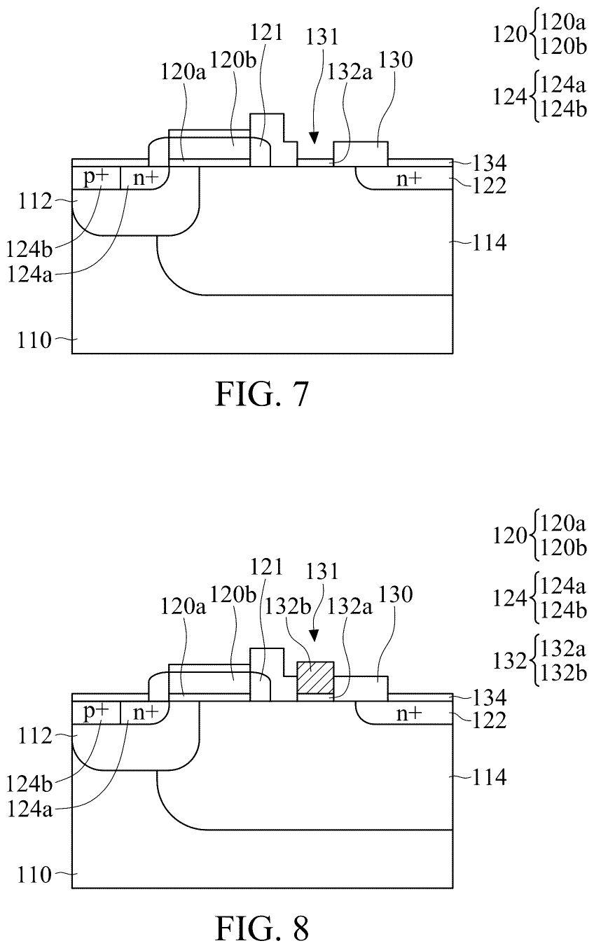

Next, referring to FIG. 7, an ohmic contact layer 132 is formed within the opening 131. In some embodiments, a self-aligned silicide process is performed on the surface of the second well region 114 exposed by the opening 131 to form a silicide layer 132a. The self-aligned silicide process forms a silicide element through a silicidation reaction. This process includes depositing a metal material onto a silicon structure (e.g., the second well region 114) and then annealing at an elevated temperature to induce a silicide reaction between the underlying silicon and the metal, thereby forming a metal silicide. For example, a metal material (e.g., nickel (Ni)) that forms ohmic contact with the second well region 114 (e.g., silicon carbide (SiC)) may be used. Then, a rapid thermal processing (RTP) silicidation process is performed to induce a silicidation reaction between Ni and SiC, forming a metal silicide (e.g., nickel silicide (NiSi)).

After forming the metal silicide, any unreacted metal material is removed through etching. In some embodiments, the self-aligned silicide process forms a silicide layer 132a and simultaneously forms self-aligned metal silicide 134 on the surfaces of the gate structure 120, the source structure 124, and the drain structure 122. In some other embodiments, the self-aligned metal silicide 134 and the silicide layer 132a are formed in different process steps. As mentioned above, during the self-aligned silicide process, the RPO layer 130 protects the underlying region (e.g., the second well region 114 and the drain structure 122) from forming silicide.

Referring to FIG. 8, a metal layer 132b is formed and stacked on the silicide layer 132a. As a result, the ohmic contact layer 132 is formed on the second well region 114, establishing ohmic contact with the second well region 114. The methods for forming the metal layer 132b are similar to those for the gate electrode 120b described in FIG. 4, and their descriptions will not be repeated herein for brevity.

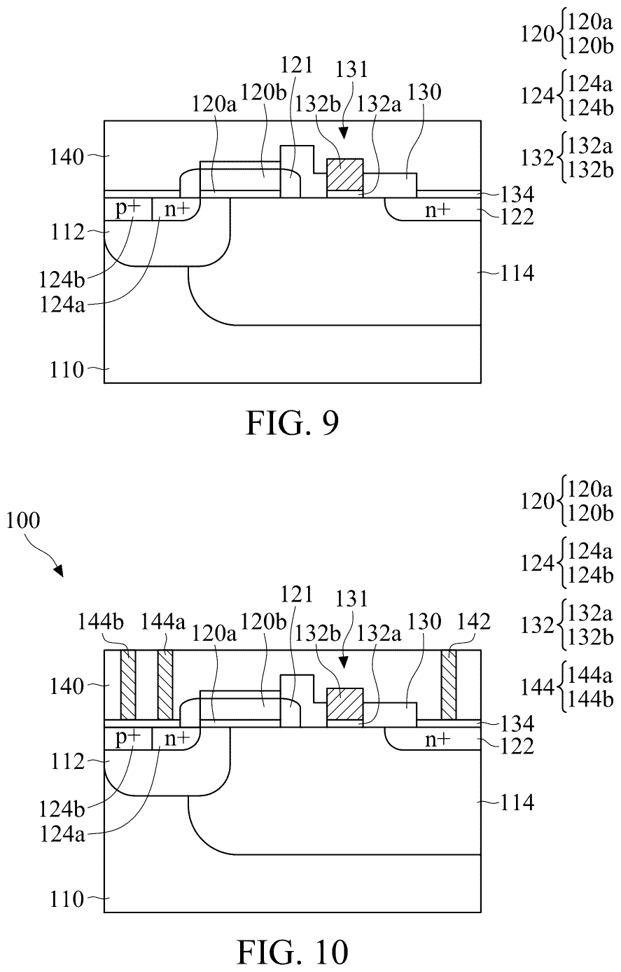

Referring to FIG. 9, an interlayer dielectric (ILD) layer 140 is blanket formed on the substrate 110. As shown in the figure, the ILD layer 140 is formed to covers the gate structure 120, the source structure 124, the drain structure 122, and the ohmic contact layer 132. The ILD layer 140 may be formed using CVD (e.g., HDPCVD, atmospheric pressure chemical vapor deposition (APCVD), low-pressure chemical vapor deposition (LPCVD), plasma enhanced chemical vapor deposition (PECVD)), PVD, ALD, spin-on coating, other suitable processes, or a combination thereof.

Referring to FIG. 10, a drain contact 142 is formed through the ILD layer 140 and electrically connected to the drain structure 122, and a source contact 144 (including a first source contact 144a and a second source contact 144b) is formed through the interlayer dielectric layer 140 and electrically connected to the source structure 124, completing the formation of the semiconductor device 100 as shown in FIG. 1. The ILD layer 140 may undergo a patterning process to form an opening, after which a conductive material is deposited to fill the opening by PVD, electroplating, ALD, other suitable processes, or a combination thereof. A planarization process (e.g., chemical mechanical polishing (CMP)) or an etching-back process may then be performed to remove the conductive material outside the opening, forming a drain contact 142 and a source contact 144. The first source contact 144a and the second source contact 144b are electrically connected to the first doped region 124a and the second doped region 124b, respectively. It should be understood that after forming the drain contact 142 and the source contact 144, subsequent processes can be carried out as necessary to complete the production of the semiconductor device 100. Since these processes are not directly related to the focus of this disclosure, they will not be described herein for brevity.

In summary, the present disclosure provides a semiconductor device and a method for forming the same. The semiconductor device includes an ohmic contact layer between a gate structure and a drain structure. The ohmic contact layer is located on the second well region (e.g., the drift region) to form ohmic contact with the second well region, ensuring that the current in the second well region is concentrated near its surface, thereby reducing the on-resistance (Ron). Furthermore, since the surface electric field can be more uniformly distributed, a better charge balance can be achieved. As a result, the off-state breakdown voltage (V_{BD}) can be maintained or increased, thereby improving the reliability of the semiconductor device.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a first well region and a second well region disposed adjacent to one another in the substrate and having opposite doping types;
a gate structure spanning the first well region and the second well region;
a source structure disposed in the first well region;
a drain structure disposed in the second well region; and
an ohmic contact layer disposed on the second well region to form ohmic contact with the second well region, wherein the ohmic contact layer is disposed between the gate structure and the drain structure.

2. The semiconductor device of claim 1, wherein the ohmic contact layer comprises a silicide layer in direct contact with the second well region.

3. The semiconductor device of claim 2, wherein the ohmic contact layer further comprises a metal layer stacked on the silicide layer.

4. The semiconductor device of claim 1, wherein the ohmic contact layer comprises a floating metal layer.

5. The semiconductor device of claim 1, wherein the ohmic contact layer has a thickness ranging from about 1 nm to about 20 nm.

6. The semiconductor device of claim 1, further comprising:
an interlayer dielectric layer disposed on the substrate and covering the gate structure, the source structure, the drain structure, and the ohmic contact layer;
a drain contact penetrating through the interlayer dielectric layer and electrically connected to the drain structure; and
a source contact penetrating through the interlayer dielectric layer and electrically connected to the source structure.

7. The semiconductor device of claim 6, wherein in a cross-sectional view, the gate structure is separated from the drain contact by a first shortest distance, the gate structure is separated from the ohmic contact layer by a second shortest distance, and a ratio of the second shortest distance to the first shortest distance is greater than about 0.3.

8. The semiconductor device of claim 7, wherein the first shortest distance is less than about 3 μm.

9. The semiconductor device of claim 7, wherein the first shortest distance is greater than a width of the ohmic contact layer.

10. The semiconductor device of claim 1, wherein the source structure comprises a first doping region and a second doping region that are adjacent to each other and have opposite doping types.

11. The semiconductor device of claim 1, wherein the drain structure has a dopant of the same doping type as the second well region, and a dopant concentration of the drain structure is greater than a dopant concentration of the second well region.

12. The semiconductor device of claim 1, further comprising:
a self-aligned metal silicide disposed on surfaces of the gate structure, the source structure, and the drain structure.

13. The semiconductor device of claim 1, further comprising:
a blocking protective oxide layer extending between the gate structure and the drain structure, wherein the ohmic contact layer is disposed on the second well region, penetrating through the barrier protective oxide layer.

14. A method for forming a semiconductor device, comprising:
providing a substrate having a first well region and a second well region disposed adjacent to one another to each other and having opposite doping types;
forming a gate structure spanning the first well region and the second well region;
forming a source structure in the first well region;
forming a drain structure in the second well region; and
forming an ohmic contact layer on the second well region to form ohmic contact with the second well region, wherein the ohmic contact layer is disposed between the gate structure and the drain structure.

15. The method of claim 14, wherein the step of forming the ohmic contact layer comprises performing a self-aligned silicide process on a surface of the second well region to form a silicide layer.

16. The method of claim 15, wherein the step of forming the ohmic contact layer further comprises forming a metal layer stacked on the silicide layer.

17. The method of claim 15, wherein the step of performing the self-aligned silicide process further comprises forming a self-aligned metal silicide on the surfaces of the gate structure, the source structure, and the drain structure, respectively.

18. The method of claim 14, further comprising:
forming a barrier protection oxide layer extending between the gate structure and the drain structure;
recessing the barrier protection oxide layer to form an opening to expose a portion of a surface of the second well region; and
forming the ohmic contact layer within the opening.

19. The method of claim 14, wherein the ohmic contact layer comprises a floating metal layer.

20. The method of claim 14, further comprising:
forming an interlayer dielectric layer on the substrate and covering the gate structure, the source structure, the drain structure, and the ohmic contact layer;
forming a drain contact penetrating through the interlayer dielectric layer and electrically connected to the drain structure; and
forming a source contact penetrating through the interlayer dielectric layer and electrically connected to the source structure.
